(19) United States
(12) Patent Application Publication
(10) Pub. No.: US 2012/0170215 A1
(43) Pub. Date: Jul. 5, 2012

(54) ENCLOSURE OF ELECTRONIC DEVICE

(75) Inventors: CHEN-LU FAN, Tu-Cheng (TW); LI-PING CHEN, Tu-Cheng (TW)

(73) Assignee: HON HAI PRECISION INDUSTRY CO., LTD., Tu-Cheng (TW)

(21) Appl. No.: 13/279,952

(22) Filed: Oct. 24, 2011

(30) Foreign Application Priority Data
Dec. 31, 2010 (CN) 201010617296.3

(51) Int. Cl. H05K 5/02

(52) U.S. Cl. 361/679.59

(57) ABSTRACT

An enclosure of electronic device includes a casing, a mounting member, and a handle. The casing comprises a side plate. The mounting member is secured to the side plate and comprises a pivoting portion, and the pivoting portion defines a limiting slot. The handle comprises a securing portion and a limiting portion extends from the securing portion. The limiting portion is engaged in the limiting slot. The securing portion is pivotably attached between the pivoting portion and the side plate.

### BACKGROUND

1. Technical Field

The present disclosure relates to enclosures of electronic devices, and particularly to an enclosure of a computer or a server.

2. Description of Related Art

Enclosures of electronic devices can include a top plate, a bottom plate, and a front plate, with a handle extending from the top plate. To move the device, a user should grasp the handle in one hand and support the device with the other. However, this method can be inconvenient. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an enclosure of electronic device.

FIG. 2 is an isometric view of the assembled enclosure of electronic device of FIG. 1, and a handle is located in a first position.

FIG. 3 is similar to FIG. 2, but the handle is located in a second position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

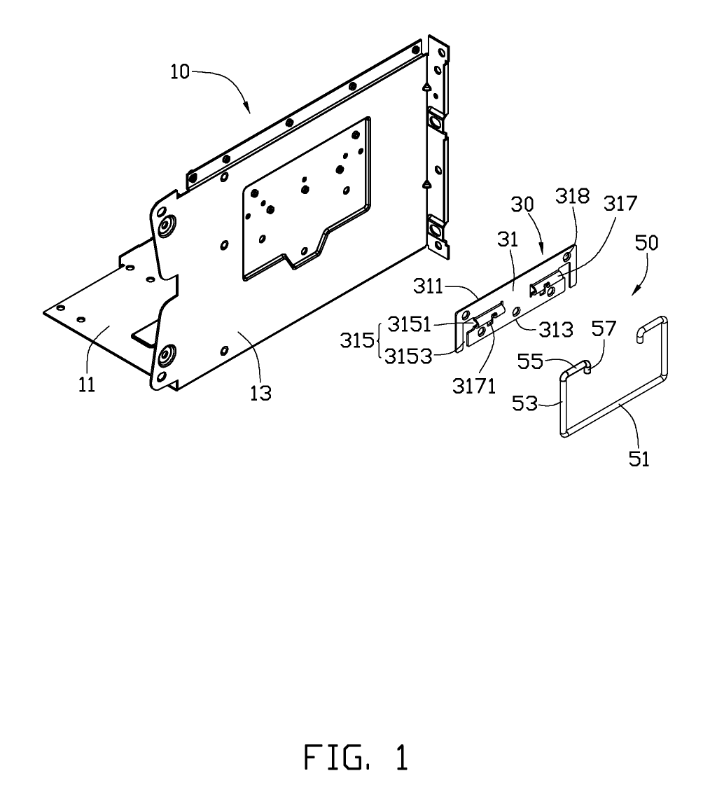

Referring to FIG. 1, an enclosure of electronic device in accordance with an embodiment includes a casing 10, a mounting member 30, and a handle 50.

The casing 10 includes a bottom plate 11 and two opposite side plates 13. In one embodiment, the bottom plate 11 is substantially perpendicular to the two side plates 13.

The mounting member 30 includes a mounting plate 31. The mounting plate 31 includes a first end 311 and a second end 313 opposite to the first end 311. The mounting plate 31 defines two positioning slots 315. Each positioning slot 315 includes a receiving slot 3151 and a guiding slot 3153 communicated with the receiving slot 3151. The guiding slot 3153 extends from the second end 313 along a first direction, which is substantially perpendicular to the second end 313. The receiving slot 3151 extends from the guiding slot 3153 along a second direction, which is substantially perpendicular to the first direction. The receiving slots 3151 of the two positioning slots extend along two opposite directions. Two pivoting portions 317 protrude from the mounting plate 31. Each pivoting portion 317 is connected to a top edge and a bottom edge of each receiving slot 3151. Each pivoting portion 317 defines a limiting slot 3171. The mounting plate further defines a plurality mounting holes 318 for securing the mounting member 30 to the casing 10.

The handle 50 includes an operating pole 51, two connecting poles 53, and two securing poles 55. The two connecting poles 53 are located on two opposite ends of the operating pole 51 and are substantially perpendicular to the operating pole 51. The two securing poles 55 extend from the top end of the connecting poles 53 and are substantially parallel to the operating pole 51. The two securing poles 55 extend toward each other. A limiting portion 57 extends from the free end of each securing pole 55. The limiting portion 57 is substantially parallel to the connecting pole 53. The handle 50 defines a plane, and the operating pole 51, the two connecting poles 53, the two securing poles 55 and the two limiting portions 57 are located in the plane.

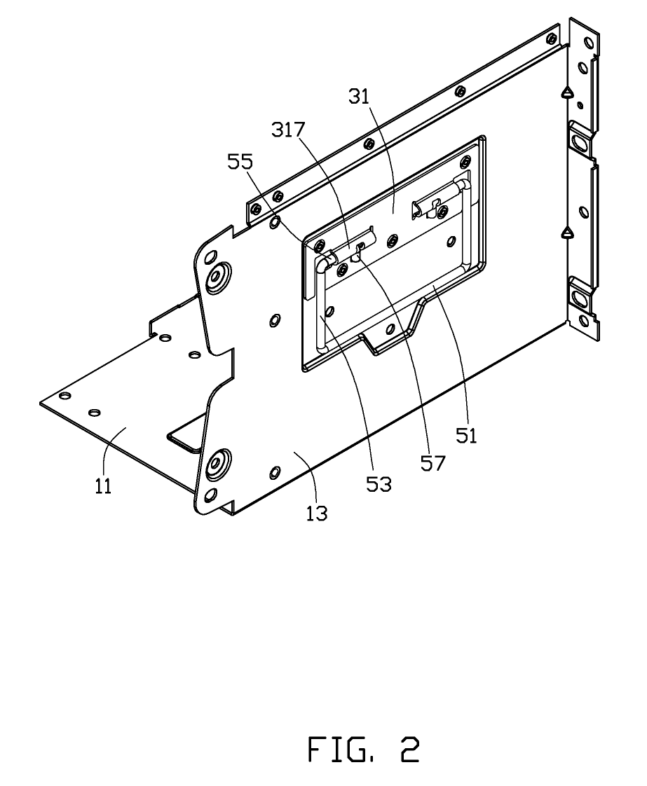

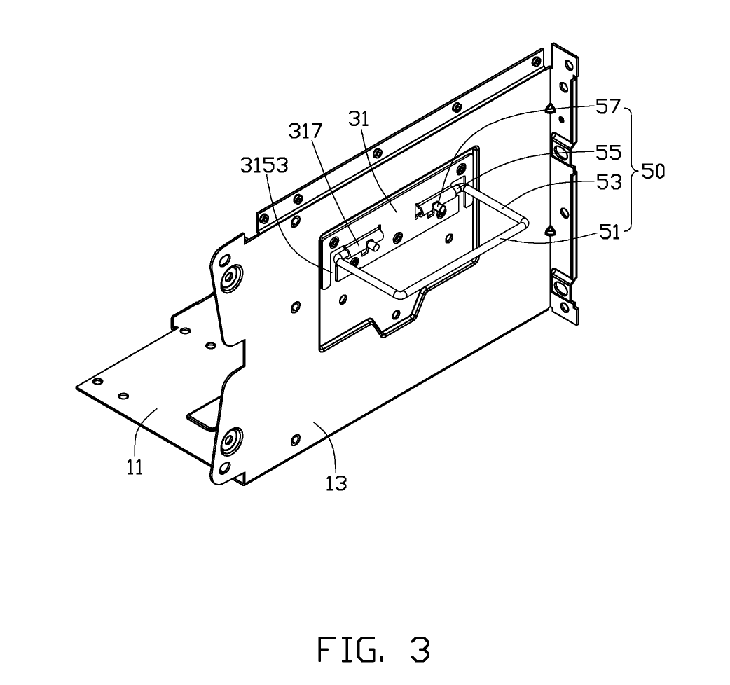

Referring to FIGS. 2 and 3, in assembly, the handle 50 is moved to be adjacent to the rear surface of the mounting member 30. The securing pole 55 is aligned with the receiving slot 3151, and the connecting pole 53 is aligned with the guiding slot 3153. The limiting portion 57 is inserted through the limiting slot 3171, and the securing pole 55 is received in the pivoting portion 317. The handle 50 is rotatably positioned in the mounting member 30 thereby. The mounting member 30 is moved towards the side plate 13 until the mounting member 30 is attached to the side plate 13. The mounting member 30 is secured to the side plate 13 by securing methods known in the art, such as screwing, soldering, or riveting. The securing pole 55 is secured between the pivoting portion 317 and the side plate 13. The limiting portion 57 is engaged in the limiting slot 3171 to prevent the handle 50 from escaping the pivoting portion 317.

The handle 50 is rotatable between a first position and a second position about the pivoting portion 317. When the handle 50 is located in the first position, the plane the handle 50 defines is substantially parallel the side plate 13, and the limiting portion 57 abuts the mounting plate 31. When the handle 50 is located in the second position, the plane the handle 50 defined is substantially perpendicular to the side plate 13, and the limiting portion 57 abuts a top edge of the limiting slot 3171. The top edge of the limiting slot 3171 prevents the handle 50 from rotating beyond the second position.

When the electronic device needs to be moved, the handle 50 is rotated from the first position to the second position, then the electronic device can be moved by pushing the handle 50.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An enclosure of electronic device comprising:
a casing comprising a side plate;
a mounting member secured to the side plate and comprising a pivoting portion, and the pivoting portion defining a limiting slot; and
a handle comprising a securing portion and a limiting portion extending from the securing portion;
wherein the limiting portion is engaged in the limiting slot, the securing portion is pivotably attached between the pivoting portion and the side plate.

2. The enclosure of electronic device of claim 1, wherein the securing portion is substantially perpendicular to the limiting portion.

3. The enclosure of electronic device of claim 1, wherein the mounting member comprises a mounting plate secured to the side plate, and the pivoting portion protrudes from the mounting plate; and the mounting plate defines a positioning slot, and the securing portion is received in the positioning slot.

4. The enclosure of electronic device of claim 3, wherein the handle further comprises a connecting portion and an operating portion, the connecting portion is located between the securing portion and the operating portion, and the operating portion is operable to rotate the handle.

5. The enclosure of electronic device of claim 4, wherein the connecting portion and the limiting portion are located on two opposite ends of the securing portion, and the connecting portion is substantially parallel to the limiting portion.

6. The enclosure of electronic device of claim 4, wherein the positioning slot comprises a receiving slot and a guiding slot, the connecting portion is received in the guiding slot, and the securing portion is received in the receiving slot.

7. The enclosure of electronic device of claim 6, wherein the receiving slot is communication with the guiding slot and is substantially perpendicular to the receiving slot.

8. The enclosure of electronic device of claim 6, wherein the mounting plate comprises a top edge and a bottom edge opposite to the top edge, and the guiding slot extends from the bottom edge along a direction substantially perpendicular to the bottom edge.

9. The enclosure of electronic device of claim 8, wherein the handle defines a plane and is rotatable between a first position and a second position, when the handle is located in the first position, the plane is substantially parallel to the side plate; when the handle is located in the second position, the plane is substantially perpendicular to the side plate.

10. The enclosure of electronic device of claim 9, wherein when the mounting member is located in the first position, the limiting portion abuts the mounting plate; when the mounting plate is located in the second position, the limiting portion abuts an edge of the limiting slot adjacent to the top edge of the mounting plate.

11. An enclosure of electronic device comprising:
a casing comprising a side plate;
a mounting member secured to the side plate and comprising a pivoting portion; and
a handle comprising a securing portion and a limiting portion extending from the securing portion;
wherein the limiting portion is engaged with the pivoting portion, and the securing portion is pivotably attached between the pivoting portion and the side plate; the handle defines a plane and is rotatable between a first position and a second position, when the handle is located in the first position, the plane is substantially parallel to the side plate; when the handle is located in the second position, the plane is substantially perpendicular to the side plate.

12. The enclosure of electronic device of claim 11, wherein the securing portion is substantially perpendicular to the limiting portion.

13. The enclosure of electronic device of claim 11, wherein the pivoting portion defines a limiting slot, and the limiting portion is engaged in the limiting slot

14. The enclosure of electronic device of claim 13, wherein the mounting member comprises a mounting plate secured to the side plate, and the pivoting portion protrudes from the mounting plate; when the mounting member is located in the first position, the limiting portion abuts the mounting plate; when the mounting plate is located in the second position, the limiting portion abuts an edge of the limiting slot.

15. The enclosure of electronic device of claim 14, wherein the mounting plate defines a positioning slot, and the securing portion is received in the positioning slot.

16. The enclosure of electronic device of claim 15, wherein the handle further comprises a connecting portion and an operating portion, the connecting portion is located between the securing portion and the operating portion, and the operating portion is operable to rotate the handle.

17. The enclosure of electronic device of claim 16, wherein the connecting portion and the limiting portion are located on two opposite ends of the securing portion, and the connecting portion is substantially parallel to the limiting portion.

18. The enclosure of electronic device of claim 16, wherein the positioning slot comprises a receiving slot and a guiding slot, the connecting portion is received in the guiding slot, and the securing portion is received in the receiving slot.

19. The enclosure of electronic device of claim 18, wherein the receiving slot is communication with the guiding slot and is substantially perpendicular to the receiving slot.

20. The enclosure of electronic device of claim 18, wherein the mounting plate comprises a top edge and a bottom edge opposite to the top edge, and the guiding slot extends from the bottom edge along a direction substantially perpendicular to the bottom edge.
